(19) United States
(12) Patent Application Publication
(10) Pub. No.: US 2024/0386951 A1
(43) Pub. Date: Nov. 21, 2024

(54) INTEGRATED CIRCUIT

(71) Applicant: TAIWAN SEMICONDUCTOR MANUFACTURING COMPANY, LTD., Hsinchu (TW)

(72) Inventor: Mei-Chen CHUANG, Hsinchu (TW)

(21) Appl. No.: 18/785,998

(22) Filed: Jul. 26, 2024

Related U.S. Application Data
(63) Continuation of application No. 18/362,393, filed on Jul. 31, 2023, now Pat. No. 12,100,445.
Application No. 18/362,393 is a division of application No. 17/463,082, filed on Aug. 31, 2021, now Pat. No. 11,837,281.

(51) Int. Cl. G11C 11/54; G06N 3/063; G11C 13/00

(52) U.S. Cl. CPC G11C 11/54; G06N 3/063; G11C 13/0002

(57) ABSTRACT

An integrated circuit includes a first array of resistors, a second array of resistors, and a plurality of interface circuits electrically coupled between the first array of resistors and the second array of resistors. Each interface circuit among the plurality of interface circuits is configured to receive a signal from the first array of resistors, and apply an analog voltage corresponding to the signal to the second array of resistors.

### RELATED APPLICATION(S)

This application is a continuation application of U.S. patent application Ser. No. 18/362,393, filed Jul. 31, 2023, which is a divisional application of U.S. patent application Ser. No. 17/463,082, filed Aug. 31, 2021, now U.S. Pat. No. 11,837,281, issued Dec. 5, 2023. The entire contents of the above-referenced patent(s) and applications are incorporated by reference herein.

### BACKGROUND

Recent developments in the field of artificial intelligence have resulted in various products and/or applications, including, but not limited to, speech recognition, image processing, machine learning, natural language processing, or the like. Such products and/or applications often use neural networks to process large amounts of data for learning, training, cognitive computing, or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a neural network, and FIG. 1B is a schematic diagram of a portion of the neural network, in accordance with some embodiments.

FIG. 2 is a schematic diagram of an integrated circuit, in accordance with some embodiments.

FIG. 3 is a schematic diagram of a memory device, in accordance with some embodiments.

FIG. 4 is a schematic block diagram of an interface circuit, in accordance with some embodiments.

FIG. 5A is a schematic circuit diagram of an interface circuit, in accordance with some embodiments.

FIG. 5B and 5C are schematic circuit diagrams of various buffer circuits, in accordance with some embodiments.

FIG. 6 is a flowchart of a method in accordance with some embodiments.

FIG. 7 is a block diagram of a computer system, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

A neural network is implemented by several matrices or arrays of resistors arranged in successive layers through which data propagate. In some embodiments, data are transferred from one resistor array to a next resistor array by analog voltages. As a result, it is possible to omit analog-to-digital conversion or analog-to-digital converters (ADCs) between successive layers in a neural network. As ADCs often occupy a large chip area, sometimes even larger than the chip area of resistor arrays, by omitting ADCs between successive layers in a neural network, at least one embodiment makes it possible to significantly reduce the chip area as well as power consumption of an integrated circuit (IC) implementing the neural network. Reduced area and power consumption in accordance with some embodiments are improvements over other approaches where ADCs are used for data conversion and/or data transfer between successive layers of a neural network.

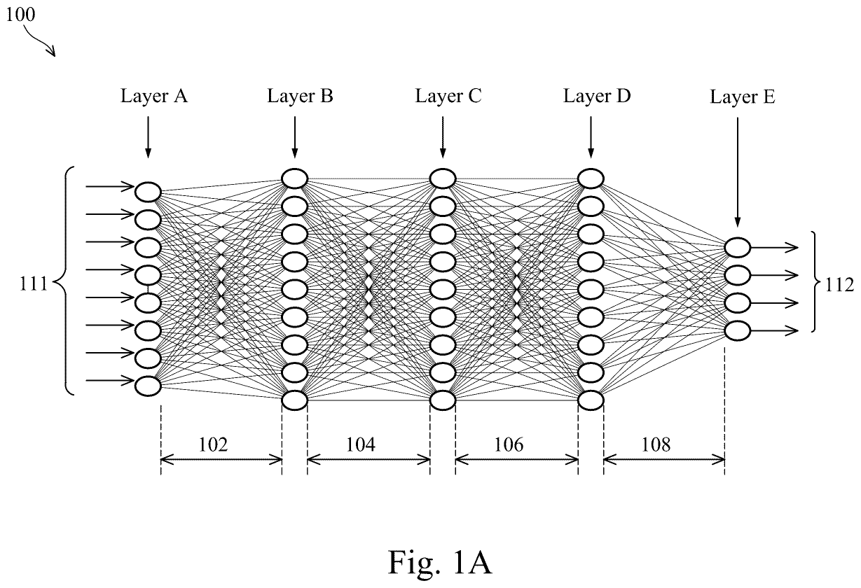

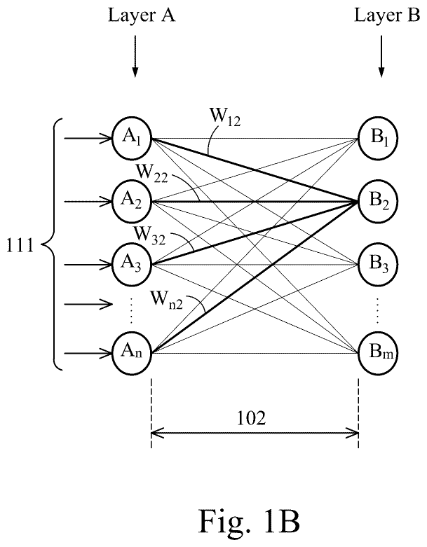

FIG. 1A is a schematic diagram of a neural network 100, in accordance with some embodiments.

The neural network 100 comprises a plurality of layers A-E each comprising a plurality of nodes (or neurons). The nodes in successive layers of the neural network 100 are connected with each other by a matrix or array of connections. For example, the nodes in layers A and B are connected with each other by connections in a matrix 102, the nodes in layers B and C are connected with each other by connections in a matrix 104, the nodes in layers C and D are connected with each other by connections in a matrix 106, and the nodes in layers D and E are connected with each other by connections in a matrix 108. Layer A is an input layer configured to receive input data 111. The input data 111 propagate through the neural network 100, from one layer to the next layer via the corresponding matrix of connections between the layers. As the data propagate through the neural network 100, the data undergo one or more computations as described with respect to FIG. 1B, and are output as output data 112 from layer E which is an output layer of the neural network 100. Layers B, C, D between input layer A and output layer E are sometimes referred to as hidden or intermediate layers. The number of layers, number of matrices of connections, and number of nodes in each layer in FIG. 1A are examples. Other configurations are within the scopes of various embodiments. For example, in at least one embodiment, the neural network 100 includes no hidden layer, and has an input layer connected by one matrix of connections to an output layer. In one or more embodiments, the neural network 100 has one, two, or more than three hidden layers.

FIG. 1B is a schematic view of the matrix 102 and associated layers A and B of the neural network 100. Other layers C, D, E and matrices 104, 106, 108 are configured similarly to layers A, B and the matrix 102, and are not described in detail herein.

As illustrated in FIG. 1B, layer A comprises n nodes identified as nodes A₁, A₂, A₃ to Aₙ, and layer B comprises m nodes identified as nodes B₁, B₂, B₃ to Bₘ, where n and m are positive integers. In some embodiments, n is equal to m. In one or more embodiments, n is different from m. In at least one embodiment, at least one of n or m is equal to 1, i.e., the corresponding layer has one node (one neuron). Each node of layer A is connected to one or more nodes of layer B, and vice versa. In the example configuration in FIG. 1B, each node of layer A is connected to all nodes of layer B, and vice versa. Other configurations are within the scopes of various embodiments. In the matrix 102, a connection between a node in layer A and another node in layer B has a corresponding weight. For example, a connection between node A₁ and node B₂ has a weight W₁₂, a connection between node A₂ and node B₂ has a weight W₂₂, a connection between node A₃ and node B₂ has a weight W₃₂, and a connection between node Aₙ and node B₂ has a weight Wₙ₂. In the description herein, a value of a node is denoted by the name of the node. For example, node A₁ has value A₁, node B₂ has value B₂, or the like.

In at least one embodiment, value B₂ at node B₂ is calculated by the following activation function (1):

$${B}_{2} = {A}_{1} \times {W}_{12} + {A}_{2} \times {W}_{22} + {A}_{3} \times {W}_{32} … + {A}_{n} \times {W}_{n 2} \qquad ( 1 )$$

A generalized form of activation function (1) is given as the following activation function (2):

$${B}_{j} = {\sum }_{i = 1}^{n} {A}_{i} \times {W}_{ij} \qquad ( 2 )$$

where i=1, 2, . . . n, j=1, 2, . . . m, and Wᵢⱼ is the weight of the connection connecting node Aᵢ and node Bⱼ.

In some embodiments, in addition to weights assigned to the connections in the matrix 102, a bias is further assigned to one or more of the nodes. For example, when a bias b is assigned to node Bⱼ, the activation function at node Bj becomes:

$${B}_{j} = b + {\sum }_{i = 1}^{n} {A}_{i} \times {W}_{ij} \qquad ( 3 )$$

The input data 111 comprise values A₁, A₂, A₃, . . . Aₙ applied to corresponding nodes A₁, A₂, A₃ to Aₙ. Values B₁, B₂, B₃ to Bₘ are calculated from input values A₁, A₂, A₃, . . . Aₙ and the corresponding weights Wᵢⱼ based on activation function (2). Calculated values B₁, B₂, B₃ to Bₘ are then used, together with corresponding weights of connections in the matrix 104, to calculate values at the nodes of layer C by using one or more corresponding activation functions. Values at the nodes in subsequent layers D and E are calculated in a similar manner, resulting in the output data 112 being output from output layer E of the neural network 100. The described activation functions (1) and (2) are examples. Other activation functions for calculating values at nodes in the neural network 100 are within the scopes of various embodiments.

In an example application of the neural network 100, learning or training is performed in the neural network 100 by applying a training set of input data to input layer A, propagating the input data through the neural network 100 by calculating values at various nodes in the neural network 100 as described herein, and collecting a set of output data from the output layer E. The collected set of output data are compared with an expected set of output data to determine an amount of error in the collected output data as compared to the expected output data. Based on the determined amount of error, one or more weights of one or more connections in the neural network 100 are adjusted with an aim to reduce the amount of error, and the process is repeated with the application of the same or a different training set of input data to the neural network 100 after weight adjustments. When the amount of error falls below a predetermined acceptable level, the neural network 100 is considered trained and can now be used to process actual input data. For example, when the neural network 100 has been trained to perform image processing, the trained neural network 100 processes one or more input images, and outputs, e.g., one or more faces recognized from the input images. The described training process and application of the neural network 100 are examples. Other applications and/or training processes are within the scopes of various embodiments.

In some embodiments, at least one matrix 102, 104, 106, 108 of connections in the neural network 100 is implemented by an array of resistors each corresponding to a weight of a connection, as described herein.

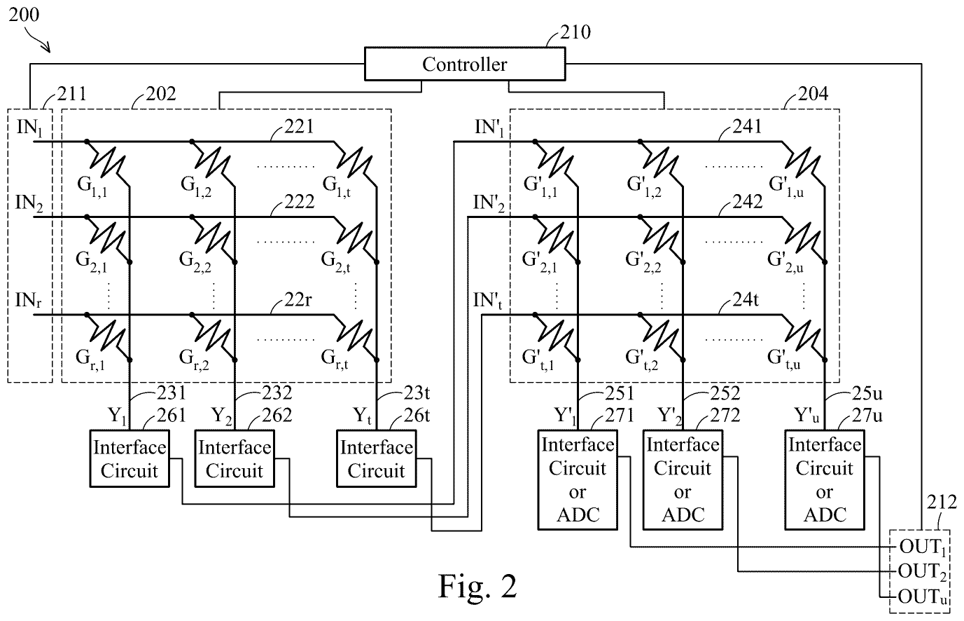

FIG. 2 is a schematic diagram of an integrated circuit (IC) 200, in accordance with some embodiments. In at least one embodiment, the IC 200 is configured as a neural network, or as a portion of a neural network as described with respect to FIGS. 1A-1B.

The IC 200 comprises a first array of resistors (or resistor array) 202, a second resistor array 204, and a controller 210.

The resistor array 202 is an r×t array, where r and t are positive integers, with r input conductive lines 221, 222, . . . 22r, and t output conductive lines 231, 232, . . . 23t. The resistor array 202 comprises a plurality of resistors. Each resistor of the resistor array 202 is electrically coupled between a corresponding input conductive line 22k (where k is 1, 2, . . . r) and a corresponding output conductive line 23l (where l is 1, 2, . . . t), and is indicated in FIG. 2 by a corresponding conductance G_{k,l} of the resistor. For example, a resistor electrically coupled between the input conductive line 221 and the output conductive line 231 is indicated in FIG. 2 by the corresponding conductance G_{1,1}. For another example, a resistor electrically coupled between the input conductive line 22ᵣ and the output conductive line 23t is indicated in FIG. 2 by the corresponding conductance G_{r,t}.

The resistor array 204 is a t×u array, where u is a positive integer, with t input conductive lines 241, 242, . . . 24t, and u output conductive lines 251, 252, . . . 25u. The resistor array 204 comprises a plurality of resistors. Each resistor of the resistor array 204 is electrically coupled between a corresponding input conductive line 24k′ (where k′ is 1, 2, . . . t) and a corresponding output conductive line 25l′ (where l′is 1, 2, . . . u), and is indicated in FIG. 2 by a corresponding conductance G′_{k′,l′}of the resistor. For example, a resistor electrically coupled between the input conductive line 241 and the output conductive line 251 is indicated in FIG. 2 by the corresponding conductance G′_{1,1}. For another example, a resistor electrically coupled between the input conductive line 24t and the output conductive line 25u is indicated in FIG. 2 by the corresponding conductance G′_{t,u}.

In some embodiments, at least one resistor in at least one of the resistor arrays 202, 204 is a controllably variable resistor having a conductance adjustable or programmable, e.g., under control of the controller 210. Example configurations of controllably variable resistors include, but are not limited to, static random-access memory (SRAM), resistive RAM (RRAM), magnetoresistive RAM (MRAM), phase change RAM (PCRAM), spin transfer torque RAM (STTRAM), floating-gate metal-oxide-semiconductor field-effect transistors (FGMOS), spintronics, or the like.

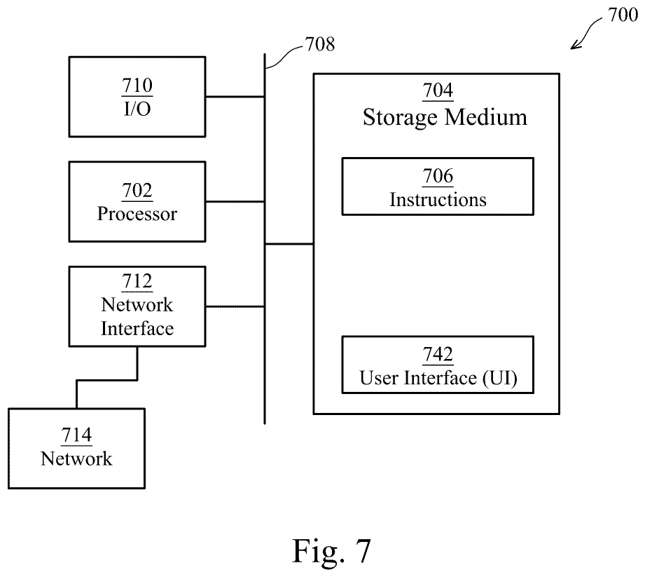

The controller 210 is electrically coupled to the resistor arrays 202, 204, and is configured to adjust the conductance of at least one resistor in the resistor arrays 202, 204, as described herein. In at least one embodiment, the controller 210 is further configured to apply input data 211 to the resistor array 202 and/or to process output data 212 output from the resistor array 204. Example hardware configurations of the controller 210 include, but are not limited to, a processor, a central processing unit (CPU), a multi-processor, a distributed processing system, an application specific integrated circuit (ASIC), or a computer system as described with respect to FIG. 7.

The IC 200 further comprises a plurality of interface circuits 261, 262, . . . 26t, each electrically coupled between a corresponding output conductive line 231, 232, . . . 23t of the resistor array 202 and a corresponding input conductive line 241, 242, . . . 24t of the resistor array 204. For example, the interface circuit 261 is electrically coupled between the output conductive line 231 of the resistor array 202 and the input conductive line 241 of the resistor array 204. For another example, the interface circuit 26t is electrically coupled between the output conductive line 23t of the resistor array 202 and the input conductive line 24t of the resistor array 204.

The IC 200 further comprises a plurality of circuits 271, 272, . . . 27u electrically coupled correspondingly to the output conductive lines 251, 252, . . . 25u of the resistor array 204. The circuits 271, 272, . . . 27u comprise ADCs or interface circuits similar to interface circuits 261, 262, . . . 26t. In the example configuration in FIG. 2, the resistor array 204 comprises the output layer of a neural network configured by the IC 200, and the circuits 271, 272, . . . 27u comprise ADCs configured to output corresponding digital signals OUT₁, OUT₂, . . . OUTᵤ in the output data 212 to be processed by the controller 210. In one or more embodiments, the resistor array 204 does not comprise the output layer of the neural network and the IC 200 further comprises a further resistor array which corresponds to the matrix 104 in FIG. 1A and is electrically coupled to the output conductive lines 251, 252, . . . 25u of the resistor array 204 through the corresponding circuits 271, 272, . . . 27u. In such embodiments, the circuits 271, 272, . . . 27u are interface circuits similar to interface circuits 261, 262, . . . 26t.

In some embodiments, resistors in at least one of the resistor arrays 202, 204 correspond to connections in a matrix described with respect to FIGS. 1A, 1B. For example, in at least one embodiment, the resistors in the resistor array 202 correspond to the connections in the matrix 102, and conductance G_{k,l} of a resistor in the resistor array 202 corresponds to weight Wᵢⱼ of the corresponding connection in the matrix 102. The input conductive lines 221, 222, . . . 22ᵣ of the resistor array 202 correspond to nodes A₁, A₂, . . . Aₙ in layer A of the neural network 100. The output conductive lines 231, 232, . . . 23t of the resistor array 202 correspond to nodes B₁, B₂, . . . Bₘ in layer B of the neural network 100. Further, the resistors in the resistor array 204 correspond to the connections in the matrix 104, and conductance G′_{k′,l′}of a resistor in the resistor array 204 corresponds to the weight of the corresponding connection in the matrix 104. The input conductive lines 241, 242, . . . 24t of the resistor array 204 correspond to nodes B₁, B₂, . . . Bₘ in layer B of the neural network 100. The output conductive lines 251, 252, . . . 25u of the resistor array 204 correspond to the nodes in layer C of the neural network 100.

The input data 211 input to the resistor array 202 corresponds to the input data 111 input to layer A. Input signals IN₁, IN₂, . . . INᵣ, in the input data 211 correspond to values A₁, A₂, . . . Aₙ input to the corresponding nodes in layer A. In at least one embodiment, input signals IN₁, IN₂, . . . INᵣ comprise analog voltages. In some embodiments, input signals IN₁, IN₂, . . . INᵣ comprise voltage pulses of corresponding digital signals. In the description herein, a voltage of a signal is denoted by the name of the signal. For example, input signal IN₁ has a voltage IN₁, input signal INᵣ, has a voltage INᵣ, or the like.

The voltage of each of input signals IN₁, IN₂, . . . INᵣ causes a corresponding current to flow from a corresponding input conductive line 22k through a corresponding resistor G_{k,l} of the resistor array 202 to a corresponding output conductive line 231. For example, the voltage of input signal IN₁ causes a corresponding current IN₁×G_{1,2} to flow from the input conductive line 221 through resistor G_{1,2} to the output conductive line 232, the voltage of input signal IN₂ causes a corresponding current IN₂×G_{2,2} to flow from the input conductive line 222 through resistor G_{2,2} to the output conductive line 232, and the voltage of input signal INᵣ, causes a corresponding current INᵣ×G_{r,2} to flow from the input conductive line 22r through resistor G_{r,2} to the output conductive line 232. The sum of the currents IN₁×G_{1,2}+IN₂×G_{2,2}+. . .INᵣ×G_{r,2} that flow from the input conductive lines 221, 222, . . . 22r to the output conductive line 232 is denoted as signal Y₂ on the output conductive line 232. In at least one embodiment, signal Y₂ corresponds to value B₂ of the corresponding node as described with respect to FIG. 1B. Signal Y₁ on the output conductive line 231 is the sum of the currents that are caused by input signals IN₁, IN₂, . . .INᵣ to flow from the input conductive lines 221, 222, . . . 22r to the output conductive line 231. Signal Yₜ on the output conductive line 23t is the sum of the currents that are caused by input signals IN₁, IN₂, . . . INᵣ to flow from the input conductive lines 221, 222, . . . 22r to the corresponding output conductive line 23t. Signals Y₁, Y₂, . . . Yₜ correspond to values of various nodes in layer B of the neural network 100. In other words, the resistor array 202 is configured to perform the calculation of activation function (1) or (2) simply by applying input signals IN₁, IN₂, . . . INᵣ to the corresponding input conductive lines 221, 222, . . . 22r to obtain signals Y₁, Y₂, . . . Yₜ on the corresponding output conductive lines 231, 232, . . . 23t.

Each of the interface circuits 261, 262, . . . 26t is configured to receive the corresponding signal Y₁, Y₂, . . . Yₜ on the corresponding output conductive line 231, 232, . . . 23t of the resistor array 202, and apply an analog voltage IN′₁, IN′₂, . . . IN′ₜ corresponding to the signal Y₁, Y₂, . . . Yₜ to the corresponding input conductive line 241, 242, . . . 24t of the resistor array 204. As a result, data transfer is performed between outputs of the resistor array 202 and inputs of the resistor array 204. This data transfer is equivalent, in one or more embodiments, to the data transfer between matrices 102, 104 through nodes B₁, B₂, . . . Bₘ in layer B of the neural network 100.

The analog voltages IN′₁, IN′₂, . . . IN′ₜ , on the input conductive line 241, 242, . . . 24t of the resistor array 204 cause currents to flow from the input conductive line 241, 242, . . . 24t to the output conductive lines 251, 252, . . . 25u through corresponding resistors of the resistor array 204. Signal Y′₁ on the output conductive line 251 is the sum of the currents that are caused by the analog voltages IN′₁, IN′₂, . . . IN′ₜ, to flow from the input conductive lines 241, 242, . . . 24t to the output conductive line 251. Signal Y′₂ on the output conductive line 252 is the sum of the currents that are caused by the analog voltages IN′₁, IN′₂, . . . IN′ₜ, to flow from the input conductive lines 241, 242, . . . 24ₜ to the output conductive line 252. Signal Y′ᵤ on the output conductive line 25u is the sum of the currents that are caused by the analog voltages IN′₁, IN′₂, . . . IN′ₜ, to flow from the input conductive lines 241, 242, . . . 24t to the output conductive line 25u.

In one or more embodiments where the circuits 271, 272, . . . 27u are interface circuits, the circuits 271, 272, . . . 27u are configured to convert signals Y′₁, Y′₂, . . . Y′ᵤ to further analog voltages to be input to a subsequent resistor array. In some embodiments where the circuits 271, 272, . . . 27u are ADCs, the circuits 271, 272, . . . 27u are configured to convert signals Y′₁, Y′₂, . . . Y′ᵤ to digital signals OUT₁, OUT₂, . . . OUTᵤ to be processed by the controller 210.

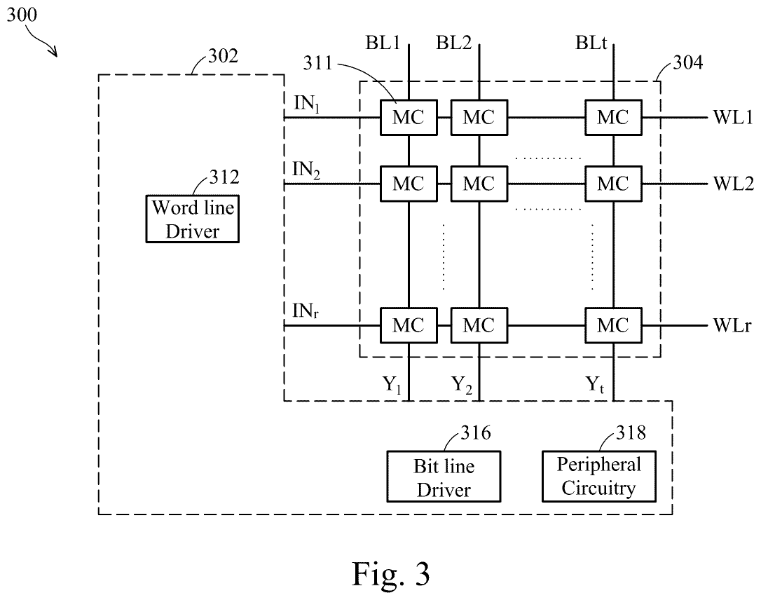

In some embodiments, the controller 210 is configured to determine an amount of error between obtained and expected output data as described herein, and, based on the determined amount of error, adjust the conductance of at least one resistor in the resistor arrays 202, 204. Conductance adjustments in the IC 200 correspond to the described weight adjustments in the neural network 100. An example configuration for conductance adjustment is described with respect to FIG. 3.

The described configuration and/or operation of the IC 200 are examples. Other configurations and/or operations are within the scopes of various embodiments. In at least one embodiment, the IC 200 comprises more than two resistor arrays. In one or more embodiments, the resistor array 202 corresponds to a matrix of connections between two hidden layers of a neural network. In such embodiments, signals IN₁, IN₂, . . . INᵣare analog voltages output by a further resistor array preceding the resistor array 202.

As described herein, the IC 200 in accordance with some embodiments comprises interface circuits 261, 262, . . . 26t configured to provide signals Y₁, Y₂, . . . Yₜ at output conductive lines 231, 232, . . . 23t of the resistor array 202 as analog voltages IN′₁, IN′₂, . . . IN′ₜ to input conductive lines 241, 242, . . . 24t of the resistor array 204. As a result, it is possible in at least one embodiment to quickly and efficiently perform data transfer between successive layers in a corresponding neural network, without performing analog-to-digital conversion or requiring ADCs. In one or more embodiments, the IC 200 achieves one or more of increased processing speed, reduced chip area cost, or reduced power consumption, compared to other approaches that include ADCs or perform analog-to-digital conversion between successive resistor arrays.

FIG. 3 is a schematic diagram of a memory device 300, in accordance with some embodiments. In some embodiments, the memory device 300 configures one or more of the matrices 102, 104, 106, 108 described with respect to FIG. 1A, or resistor arrays 202, 204 described with respect to FIG. 2.

The memory device 300 comprises a plurality of memory cells MC, and a memory controller 302 electrically coupled to the memory cells MC and configured to control operations of the memory cells MC including, but not limited to, a read operation, a write operation, or the like. Write operations include, but are not limited to, programming operation, set operation, reset operations, or the like. In at least one embodiment, the memory controller 302 corresponds to the controller 210 described with respect to FIG. 2.

The memory cells MC are arranged in a plurality of columns and rows in a memory array 304. In at least one embodiment, each of the memory cells MC represents a resistor in a resistor array as described with respect to FIG. 2. For example, the memory cell 311 represents a resistor corresponding to the resistor G_{1,1} in the resistor array 202 of the IC 200.

The memory device 300 further comprises a plurality of word lines (also referred to as “address lines”) WL1 to WLr extending along the rows, and a plurality of bit lines (also referred to as “data lines”) BL1 to BLt extending along the columns of the memory cells MC. Each of the memory cells MC is electrically coupled to the memory controller 302 by at least one of the word lines, and at least one of the bit lines. In some example operations, word lines are configured for transmitting addresses of the memory cells MC to be read from, or for transmitting addresses of the memory cells MC to be written to, or the like. In at least one embodiment, a set of word lines is configured to perform as both read word lines and write word lines. Examples of bit lines include read bit lines for transmitting data read from the memory cells MC indicated by corresponding word lines, write bit lines for transmitting data to be written to the memory cells MC indicated by corresponding word lines, or the like. In at least one embodiment, a set of bit lines is configured to perform as both read bit lines and write bit lines. The word lines are commonly referred to herein as WL, and the bit lines are commonly referred to herein as BL. Various numbers of word lines and/or bit lines in the memory array 304 are within the scope of various embodiments. In some embodiments, each memory cell MC is coupled to additional conductive lines, such as source lines and/or drain lines. Example memory types of the memory cells MC include, but are not limited to, SRAM, RRAM, MRAM, PCRAM, STTRAM), or the like. In one or more example embodiments described herein, the memory cells MC include RRAM memory cells.

In the example configuration in FIG. 3, the controller 302 comprises a word line driver 312, a bit line driver 316, and peripheral circuitry 318. In at least one embodiment, the controller 302 further includes one or more clock generators for providing clock signals for various components of the memory device 300, one or more input/output (I/O) circuits for data exchange with external devices, and/or one or more controllers for controlling various operations in the memory device 300.

The word line driver 312 is coupled to the memory array 304 via the word lines WL. The word line driver 312 is configured to decode a row address of the memory cell MC selected to be accessed in a read operation or a write operation. The word line driver 312 is configured to supply a voltage to the selected word line WL corresponding to the decoded row address, and a different voltage to the other, unselected word lines WL. The bit line driver 316 is coupled to the memory array 304 via the bit lines BL. The bit line driver 316 is configured to decode a column address of the memory cell MC selected to be accessed in a read operation or a write operation. The bit line driver 316 is configured to supply a voltage to the selected bit line BL corresponding to the decoded column address, and a different voltage to the other, unselected bit lines BL. The peripheral circuitry 318 is coupled to the memory array 304 via the bit lines BL, and comprises interface circuits or ADCs corresponding to those described with respect to FIG. 2.

In at least one embodiment, each memory cell MC corresponds to a resistor in the resistor array 202, 204, the word lines WL correspond to the input conductive lines 221, 222, . . . 22r or the input conductive lines 241, 242, . . . 24t, and the bit lines BL correspond to the output conductive lines 231, 232, . . . 23t or the output conductive lines 251, 252, . . . 25u. In some embodiments, each memory cell MC has two possible states corresponding to two conductance values of a corresponding resistor, or corresponding to two weight values of a connection in a neural network. In at least one embodiment, each memory cell MC has more than two possible states corresponding to more than two conductance values of a corresponding resistor, or corresponding to more than two weight values of a connection in a neural network. In some embodiments, each memory cell MC comprises multiple memory elements coupled together in parallel and/or in series to increase the number of possible states of the memory cell MC, to therefore increase the number of possible weight values of a connection in a neural network. Other configurations are within the scopes of various embodiments.

To switch a memory cell MC between different states, corresponding to conductance adjustment of a corresponding resistor as described herein, one or more write operations are performed by applying predetermined voltages to the bit lines BL and word lines WL. For example, when a memory cell 311 coupled to bit line BL1 and word line WL1 is selected to be accessed or programed in a write operation, a write voltage is applied by the controller 302 across the corresponding selected bit line BL1 and word line WL1, whereas the other, non-selected bit lines BL2-BLt and word lines WL2-WLr are biased at a voltage of about half the write voltage. The write voltage across the selected memory cell 311 is sufficient to switch the memory cell 311 from one logic state (e.g., logic “1”) to another logic state (e.g., logic “0”) which corresponds to conductance adjustment of a resistor represented by the memory cell 311. The biasing voltages across the other, non-elected memory cells are not sufficient to affect the logic states of the non-elected memory cells, and therefore, conductance values of resistors represented by the other, non-elected memory cells are not adjusted. In some embodiments, more than one memory cells are written to or programed in a common write operation.

To propagate data through the memory array 304 to perform computations corresponding to, for example, activation function (1) or (2) as described, a read operation is performed for the memory cells MC in the memory array 304. For example, the word lines WL1-WLr are selected or enabled by the controller 302 at the same time. Input signals, e.g., IN₁-INᵣ, as described with respect to FIG. 2, are simultaneously applied by the controller 302 to the selected word lines WL1-WLr, and cause corresponding currents to flow, through the memory cells MC of the memory array 304, to the bit lines BL1-BLt. The value of the current flowing through each memory cell MC corresponds to the input signal applied to the corresponding word line WL coupled to the memory cell MC, and also corresponds to the logic state of the memory cell MC, i.e., corresponds to the conductance value of the resistor represented by the memory cell MC. Each of signals Y₁, Y₂, . . . Yₜ, as described with respect to FIG. 2, is the sum of the values of the currents flowing through the memory cells MC coupled to a corresponding bit line BL. The signals Y₁, Y², . . . Yₜ, are supplied to the peripheral circuitry 318. In some embodiments, the peripheral circuitry 318 comprise interface circuits electrically coupled correspondingly to the bit lines BL, and configured to convert the signals Y₁, Y₂, . . . Yₜ into analog voltages to be supplied to a further memory array corresponding to a resistor array successive to the resistor array represented by the memory array 304. In some embodiments, the peripheral circuitry 318 comprise ADCs electrically coupled correspondingly to the bit lines BL, and configured to convert the signals Y₁, Y₂, . . . Yₜ into digital signals to be processed by the controller 302 or another controller corresponding to the controller 210. In some embodiments, the input signals IN₁, IN₂, INᵣ, are analog voltages applied from interface circuits associated with another memory array corresponding to a resistor array preceding the resistor array represented by the memory array 304.

The described configuration and/or operation of the memory device 300 are examples. Other configurations and/or operations are within the scopes of various embodiments. For example, in the described example configuration, the bit lines BL and word lines WL are used for both write and read operations. In one or more further embodiments, the bit lines BL and/or the word lines WL are used in write operations, and additional input and/or output conductive lines are coupled to the memory cells MC to be used in read operations. In some other embodiments, the bit lines BL and/or the word lines WL are used as input and/or output conductive lines in read operations, and additional conductive lines are coupled to the memory cells MC to be used in write operations. In at least one embodiment, one or more advantages described herein with respect to the IC 200 are achievable by the memory device 300.

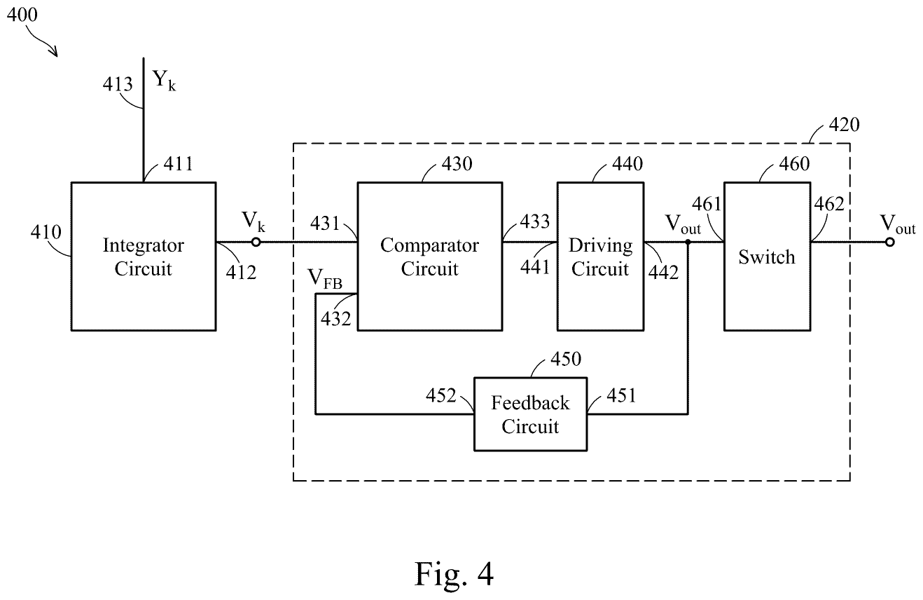

FIG. 4 is a schematic block diagram of an interface circuit 400, in accordance with some embodiments. In some embodiments, the interface circuit 400 corresponds to one or more of the interface circuits described with respect to FIGS. 2, 3. In example embodiments described herein, the interface circuit 400 corresponds to one of the interface circuits 261, 262, . . . 26t.

The interface circuit 400 comprises an integrator circuit 410, and a buffer circuit 420.

The integrator circuit 410 has an input 411 and an output 412. The input 411 is electrically coupled to an output conductive line 413 from a resistor array as described herein. In some embodiments, the output conductive line 413 corresponds to one of the output conductive lines 231, 232, . . . 23t of the resistor array 202, and a signal Yₖ corresponding to one of the signals Y₁, Y₂, . . . Yₜ is supplied by the conductive line 413 to the integrator circuit 410. The signal Yₖ corresponds to the sum of currents flowing on the conductive line 413 when a set of input data is applied to the input conductive lines of the resistor array, as described herein. The integrator circuit 410 is configured to integrate the signal Yₖ over time, e.g., over the duration of a read operation, to generate an intermediate voltage Vₖ at the output 412.

The buffer circuit 420 is electrically coupled to the output 412 of the integrator circuit 410 to receive the intermediate voltage Vₖ, and is configured to generate an analog voltage Vₒᵤₜ corresponding to the intermediate voltage Vₖ. In some embodiments, the analog voltage Vₒᵤₜ is applied to a corresponding input conductive line of a subsequent resistor array. For example, the analog voltage Vₒᵤₜ is applied, as one of the analog voltages IN′₁, IN′₂, . . . IN′ₜ, to the corresponding input conductive lines 241, 242, . . . 24t of the resistor array 204, as described herein.

In the example configuration in FIG. 4, the buffer circuit 420 comprises a comparator circuit 430, a driving circuit 440, a feedback circuit 450, and a switch 460. The comparator circuit 430 has a first input 431, a second input 432, and an output 433. The driving circuit 440 has an input 441 and an output 442. The feedback circuit 450 has an input 451 and an output 452. The switch 460 has a first end 461, and a second end 462. The first input 431 of the comparator circuit 430 is electrically coupled to the output 412 of the integrator circuit 410 to receive the intermediate voltage Vₖ. The second input 432 of the comparator circuit 430 is electrically coupled to the output 452 of the feedback circuit 450 to receive a feedback voltage V_{FB}. The comparator circuit 430 is configured to compare the intermediate voltage Vₖ at the first input 431 with the feedback voltage V_{FB} at the second input 432, and output a result of the comparison as a control signal at the output 433. The input 441 of the driving circuit 440 is electrically coupled to the output 433 of the comparator circuit 430 to receive the control signal. The driving circuit 440 is configured to generate the analog voltage Vₒᵤₜ at the output 442. The input 451 of the feedback circuit 450 is electrically coupled to the output 442 of the driving circuit 440 to receive the analog voltage Vₒᵤₜ. The feedback circuit 450 is configured to generate the feedback voltage V_{FB} corresponding to the analog voltage Vₒᵤₜ at the output 452, to apply the feedback voltage V_{FB} to the second input 432 of the comparator circuit 430. The first end 461 of the switch 460 is electrically coupled to the output 442 of the driving circuit 440. The second end 462 of the switch 460 configures an output of the buffer circuit 420.

When the switch 460 is closed, the analog voltage Vₒᵤₜ is output from the buffer circuit 420 to be applied to a corresponding input conductive line in the subsequent resistor array. When the switch 460 is open, the analog voltage Vₒᵤₜ is not output from the buffer circuit 420. A reason for controlling the switch 460 to be open is to ensure stable or correct operation of the interface circuit 400, buffer circuit 420, or other circuitry that is electrically coupled to the output of the buffer circuit 420. In some embodiments, the switch 460 is controlled to be closed or open by a controller as described. In at least one embodiment, the switch 460 is omitted.

The comparator circuit 430 is configured to control the driving circuit 440 to generate the analog voltage Vₒᵤₜ in accordance with a result of the comparison between the intermediate voltage Vₖ and the feedback voltage V_{FB}. For example, when the feedback voltage V_{FB} is smaller than the intermediate voltage Vₖ, the control signal output by the comparator circuit 430 to the input 441 of the driving circuit 440 causes the driving circuit 440 to increase the analog voltage Vₒᵤₜ. When the feedback voltage V_{FB} is greater than the intermediate voltage Vₖ, the control signal output by the comparator circuit 430 to the input 441 of the driving circuit 440 causes the driving circuit 440 to decrease the analog voltage Vₒᵤₜ. In either case, the difference between the intermediate voltage Vₖ and the feedback voltage V_{FB} is decreased, and the corresponding control signal causes the driving circuit 440 to move a voltage value of the analog voltage Vₒᵤₜ toward a stable voltage value. The stable voltage value of the analog voltage Vₒᵤₜ, or a stable state of the driving circuit 440, is reached when the feedback voltage V_{FB} becomes equal to the intermediate voltage Vₖ. In other words, the buffer circuit 420 is configured to force the feedback voltage V_{FB} (which corresponds to the analog voltage Vₒᵤₜ) to be aligned with the intermediate voltage Vₖ, in one or more embodiments. At the stable state, the analog voltage Vₒᵤₜ corresponds to the intermediate voltage Vₖ and the signal Yₖ on the conductive line 413. As a result, when the analog voltage Vₒᵤₜ is applied to a corresponding input conductive line of a subsequent resistor array, data transfer from the resistor array which outputs the signal Yₖ and the subsequent resistor array is quickly and efficiently achieved, in at least one embodiment.

A reason the buffer circuit 420 is included in the interface circuit 400 in accordance with some embodiments is that the intermediate voltage Vₖ, while corresponding to the signal Yₖ output from the resistor array, does not have sufficient current loading capability in some situations. As described with respect to FIG. 2, a voltage applied to an input conductive line of a resistor array is also applied to multiple resistors coupled to the input conductive line. In some situations, if the intermediate voltage Vₖ is directly applied to an input conductive line of the subsequent resistor array, the current loading capability at the output 412 of the integrator circuit 410 may not be sufficient to drive a large number of resistors coupled to the input conductive line, causing the intermediate voltage Vₖ to drop and resulting in inaccurate operation of the interface circuit 400. In some embodiments, the driving circuit 440 in the buffer circuit 420 is configured to provide sufficient current loading capability to ensure that the analog voltage Vₒᵤₜ does not drop and remains stable even when the analog voltage Vₒᵤₜ is applied to multiple resistors coupled to the corresponding input conductive line in the subsequent resistor array. In at least one embodiment, one or more advantages described herein with respect to the IC 200 and/or memory device 300 are achievable by the interface circuit 400.

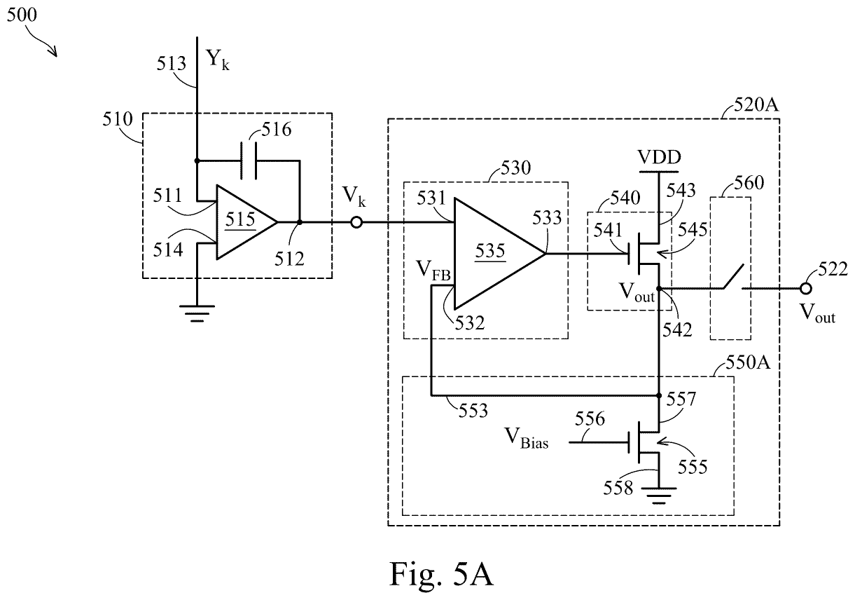

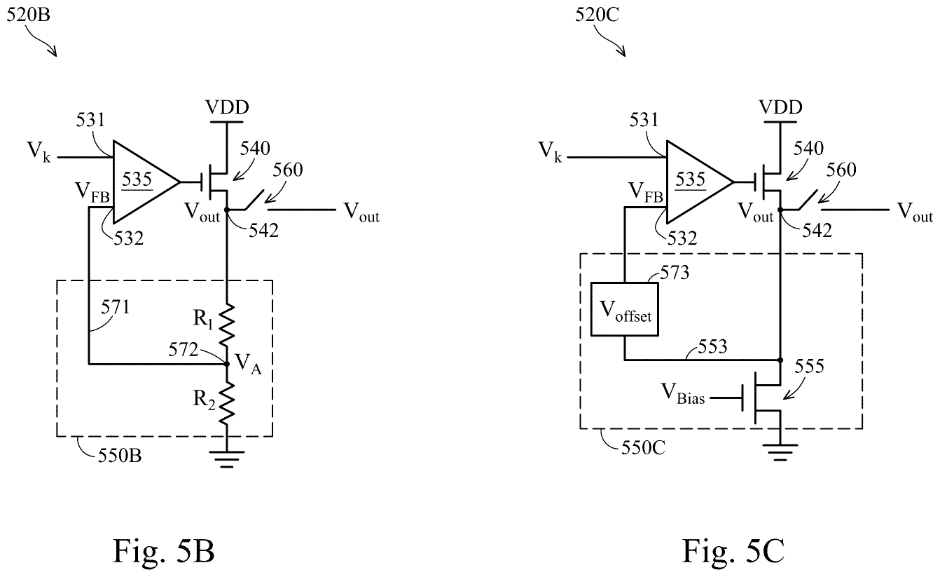

FIG. 5A is a schematic circuit diagram of an interface circuit 500, in accordance with some embodiments. In at least one embodiment, the interface circuit 500 corresponds to the interface circuit 400, or one or more of the interface circuits described with respect to FIGS. 2, 3. Components in FIG. 5A having corresponding components in FIG. 4 are designated by the reference numerals of FIG. 4 increased by 100.

The interface circuit 500 comprises an integrator circuit 510, and a buffer circuit 520A. The buffer circuit 520A comprises a comparator circuit 530, a driving circuit 540, a feedback circuit 550A, and a switch 560.

The integrator circuit 510 comprises an operational amplifier 515 and a capacitor 516. An input 511 of the operational amplifier 515 is electrically coupled to an output conductive line 513 from a resistor array to receive a signal Yₖ, as described herein. A further input 514 of the operational amplifier 515 is grounded. The capacitor 516 is electrically coupled between the input 511 and an output 512 of the operational amplifier 515. The operational amplifier 515 and the capacitor 516 are configured to integrate the signal Yₖ over time to generate an intermediate voltage Vₖ. The described configuration of the integrator circuit 510 is an example. Other integrator circuit configurations are within the scopes of various embodiments.

The comparator circuit 530 comprises an operational amplifier 535. A first input 531 of the operational amplifier 535 is electrically coupled to the output 512 of the operational amplifier 515 to receive the intermediate voltage Vₖ. A second input 532 of the operational amplifier 535 is electrically coupled to the feedback circuit 550A to receive a feedback voltage V_{FB}. The operational amplifier 535 is configured to compare the intermediate voltage Vₖ at the first input 531 with the feedback voltage V_{FB} at the second input 532, and output a result of the comparison as a control signal at an output 533 of the operational amplifier 535. The described configuration of the comparator circuit 530 is an example. Other comparator circuit configurations are within the scopes of various embodiments.

The driving circuit 540 comprises a transistor 545. The transistor 545 has a gate terminal 541 electrically coupled to the output 533 of the operational amplifier 535 to receive the control signal. The transistor 545 further has a first source/drain terminal 542 configuring the output of the driving circuit 540, and a second source/drain terminal 543 electrically coupled to a node of a power supply voltage VDD. The transistor 545 is configured to generate the analog voltage Vₒᵤₜ at the output 542, based on the control signal at the gate terminal 541. Examples of transistor 545 include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), FinFETs, planar MOS transistors with raised source/drains, or the like. In some embodiments, the transistor 545 is a p-channel metal-oxide semiconductor (PMOS) transistor, the first source/drain terminal 542 is a drain of the PMOS transistor, the second source/drain terminal 543 is a source of the PMOS transistor, the first input 531 of the operational amplifier 535 is an inverting input, and the second input 532 of the operational amplifier 535 is a non-inverting input. In some embodiments, the transistor 545 is an n-channel metal-oxide semiconductor (NMOS) transistor, the first source/drain terminal 542 is a source of the NMOS transistor, the second source/drain terminal 543 is a drain of the NMOS transistor, the first input 531 of the operational amplifier 535 is a non-inverting input, and the second input 532 of the operational amplifier 535 is an inverting input. The power provided by VDD ensures sufficient current loading capability of the driving circuit 540, as described herein. The described configuration of the driving circuit 540 is an example. Other driving circuit configurations are within the scopes of various embodiments.

The feedback circuit 550A comprises a connector 553 and a transistor 555. The connector 553 has a first end electrically coupled to the output 542 of the driving circuit 540, and a second end electrically coupled to the second input 532 of the operational amplifier 535. The transistor 555 has a controllable gate terminal 556 configured to receive a bias voltage V_{Bias}, a first source/drain terminal 557 electrically coupled to the output 542 of the driving circuit 540 and the first end of the connector 553, and a second source/drain terminal 558 which is grounded. The connector 553 applies the analog voltage Vₒᵤₜ as the feedback voltage V_{FB} to the second input 532 of the operational amplifier 535. In other words, V_{FB}=Vₒᵤₜ in the example configuration in FIG. 5A. The buffer circuit 520A reaches a stable state when V_{FB}=Vₒᵤₜ=Vₖ. The transistor 555 is configured to provide an appropriate tail current for the operational amplifier 535 to be stable in a standby state, and/or to prevent breakdown of circuit elements due to excessive currents. In some embodiments, the bias voltage V_{Bias} is provided by a controller as described herein, and/or is adjustable depending on one or more operating conditions of the interface circuit 500. In at least one embodiment, the transistor 555 is a PMOS transistor. In some embodiments, the transistor 555 is an NMOS transistor. The described configuration of the feedback circuit 550A is an example. Other feedback circuit configurations are within the scopes of various embodiments.

The switch 560 is electrically coupled between the output 542 of the driving circuit 540 and an output 522 of the interface circuit 500. The switch 560 is configured to selectively or controllably isolate the interface circuit 500 from other circuitry for one or more reasons discussed herein. In some embodiments, the switch 560 is controlled to be closed or open by a controller. For example, the switch 560 comprises a transistor having a gate terminal controlled by a controller. In at least one embodiment, the transistor of the switch 560 is a PMOS transistor. In some embodiments, the transistor of the switch 560 is an NMOS transistor. The described configuration of the switch 560 is an example. Other switch configurations are within the scopes of various embodiments. In at least one embodiment, the switch 560 is omitted.

In some embodiments, the interface circuit 500 is configured to operate in a manner described with respect to the interface circuit 400. Compared to ADCs used in other approaches for data conversion and/or data transfer between successive layers or resistor arrays, the buffer circuit 520A has a smaller footprint, lower power consumption, and shorter latency (i.e., faster speed). In some embodiments, the buffer circuit 520A has a footprint of about 10 times smaller than an ADC, and power consumption of about 100 times lower than an ADC. In at least one embodiment, one or more advantages described herein with respect to one or more of the IC 200, the memory device 300, or the interface circuit 400, are achievable by the interface circuit 500.

FIG. 5B is schematic circuit diagram of a buffer circuit 520B, in accordance with some embodiments. In some embodiments, the buffer circuit 520B is electrically coupled to the integrator circuit 510 to receive the intermediate voltage Vₖ and configure an interface circuit corresponding to the interface circuit 500. Components in FIG. 5B having corresponding components in FIG. 5A are designated by the same reference numerals as in FIG. 5A.

The buffer circuit 520B in FIG. 5B differs from the buffer circuit 520A in FIG. 5A at the feedback circuit. Specifically, a feedback circuit 550B in the buffer circuit 520B comprises a resistor divider having resistors R1, R2 electrically coupled in series between the output 542 of the driving circuit 540 and the ground. The feedback circuit 550B further comprises a connector 571 having a first end electrically coupled to a node 572 between the resistors R1, R2, and a second end electrically coupled to the second input 532 of the operational amplifier 535.

In operation, a voltage V_{A} at the node 572 is applied as the feedback voltage V_{FB} to the second input 532 of the operational amplifier 535. The feedback voltage V_{FB} is determined as follows: V_{FB}=V_{A}=Vₒᵤₜ×R2/(R1+R2). When the stable state is reached, Vₖ=V_{FB} and, therefore, Vₒᵤₜ=Vₖ×(R1+R2)/R2=Vₖ×(1+R1/R2), i.e., Vₒᵤₜ>Vₖ. As a result, it is possible to increase the analog voltage Vₒᵤₜ applied to the subsequent resistor array without increasing, or even while decreasing, the intermediate voltage Vₖ output from the integrator circuit 510. In at least one embodiment, even when the sum of the currents in signal Yₖ (and, hence, the intermediate voltage Vₖ) is small, it is possible to apply a corresponding analog voltage Vₒᵤₜ of a sufficient voltage level to the subsequent resistor array, to ensure proper and/or reliable operation of the interface circuit and/or the IC including the interface circuit. In at least one embodiment, one or more advantages described herein with respect to one or more of the IC 200, the memory device 300, the interface circuit 400, or the interface circuit 500 are achievable by the buffer circuit 520B.

FIG. 5C is schematic circuit diagram of a buffer circuit 520C, in accordance with some embodiments. In some embodiments, the buffer circuit 520C is electrically coupled to the integrator circuit 510 to receive the intermediate voltage Vₖ and configure an interface circuit corresponding to the interface circuit 500. Components in FIG. 5C having corresponding components in FIG. 5A are designated by the same reference numerals as in FIG. 5A.

The buffer circuit 520C in FIG. 5C differs from the buffer circuit 520A in FIG. 5A at the feedback circuit. Compared to the feedback circuit 550A in the buffer circuit 520A, a feedback circuit 550C in the buffer circuit 520C comprises, besides the connector 553 and transistor 555, an offset voltage circuit 573 electrically coupled to the connector 553. The offset voltage circuit 573 is configured to apply an offset voltage to the second input 532 of the operational amplifier 535.

For example, the analog voltage Vₒᵤₜ is applied from the output 542 to the offset voltage circuit 573, and is offset at the offset voltage circuit 573 by an offset voltage V_{offset} before being applied to the second input 532 of the operational amplifier 535. The offset voltage circuit 573 is configured to cause the offset voltage V_{offset} to be either added to Vₒᵤₜ or subtracted from Vₒᵤₜ. In some embodiments, the offset voltage V_{offset} is a positive voltage value and is subtracted from Vₒᵤₜ, resulting in V_{FB} =Vₒᵤₜ−V_{offset}. At the stable state, Vₖ=V_{FB} and Vₒᵤₜ=Vₖ+V_{offset}. As described herein, Vₖ corresponds to Yₖ, which in turn, corresponds to the sum of currents expressed by Σᵢ₌₁ⁿAᵢ×Wᵢⱼ in activation functions (2), (3). The additional component V_{offset} corresponds to bias b in activation function (3). In other words, the feedback circuit 550C makes it possible, in one or more embodiments, to add an assigned bias b to a node to realize activation function (3). When the bias b to be added is positive, the offset voltage circuit 573 is configured to add a positive offset voltage V_{offset} to analog voltage Vₒᵤₜ, or to subtract a negative offset voltage V_{offset} from the analog voltage Vₒᵤₜ. An example circuit configuration of the offset voltage circuit 573 comprises a positive and/or negative power supply voltage supplied via an adjustable resistor to the connector 553. Controlling the adjustable resistor, e.g., by a controller as described herein, adjusts the voltage value and/or polarity of the offset voltage V_{offset}, resulting in an intended bias b. The described configuration of the offset voltage circuit 573 is an example. Other circuit configurations for applying offset voltages are within the scopes of various embodiments.

In at least one embodiment, an offset voltage circuit corresponding to the offset voltage circuit 573 is included in the connector 571 of the feedback circuit 550B in FIG. 5B. In such embodiment, Vₒᵤₜ=(Vₖ+V_{offset})×(1+R1/R2). In at least one embodiment, one or more advantages described herein with respect to one or more of the IC 200, the memory device 300, the interface circuit 400, or the interface circuit 500 are achievable by the buffer circuit 520C.

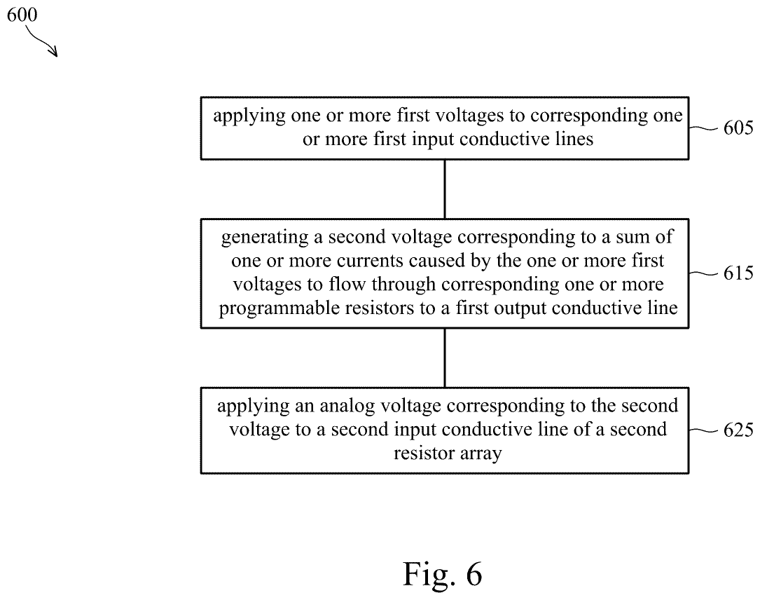

FIG. 6 is a flowchart of a method 600 in accordance with some embodiments. In at least one embodiment, the method 600 is performed in or by one or more ICs, memory devices, interface circuits, or buffer circuits described with respect to FIGS. 2-4 and 5A-5C.

At operation 605, one or more first voltages are applied to corresponding one or more first input conductive lines. For example, as described with respect to FIG. 2, voltages or input signals IN₁, IN₂, . . . INᵣ are applied to first input conductive lines 221, 222, . . . 22r in a first resistor array 202. A first output conductive line 232 is electrically coupled to the first input conductive lines 221, 222, . . . 22r through corresponding programmable resistors G_{1,2}, G_{2,2}, G_{r,2} of the resistor array 202.

At operation 615, a second voltage is generated, wherein the second voltage corresponds to a sum of one or more currents caused by the one or more first voltages to flow through corresponding one or more programmable resistors to the first output conductive line. For example, as described with respect to FIG. 2, the input signal IN₁ causes a corresponding current IN₁×G_{1,2} to flow from the input conductive line 221 through resistor G_{1,2} to the output conductive line 232, the input signal IN2 causes a corresponding current IN₂×G_{2,2} to flow from the input conductive line 222 through resistor G_{2,2} to the output conductive line 232, and the input signal INᵣ, causes a corresponding current INᵣ×G_{r,2} to flow from the input conductive line 22ᵣ through resistor G_{r,2} to the output conductive line 232. The sum of the currents IN₁×G_{1,2}+IN₂×G_{2,2}+. . . INᵣ×G_{r,2} that flow from the input conductive lines 221, 222, . . . 22r to the output conductive line 232 is denoted as signal Y₂ on the output conductive line 232. A second voltage corresponding to the signal Y₂, or the sum of currents flowing on the output conductive line 232, is generated by an interface circuit 262. In some embodiments, the second voltage corresponds to the intermediate voltage Vₖ described with respect to FIGS. 4 and 5A-5C.

At operation 625, an analog voltage corresponding to the second voltage is applied to a second input conductive line of a second resistor array. For example, as described with respect to FIGS. 4 and 5A-5C, an analog voltage Vₒᵤₜ corresponding to the second voltage Vₖ is generated, and applied to an input conductive line of a subsequent resistor array. In the example configuration in FIG. 2, the analog voltage corresponds to analog voltage IN′₂ applied to a second input conductive line 242 of a second resistor array 204.

In at least one embodiment, the analog voltage (e.g., Vₒᵤₜ) is generated from the second voltage (e.g., Vₖ) without performing an analog-to-digital conversion, as described herein.

In some embodiments, operations 605, 615, 625 correspond to a computation of an activate function at a node (e.g., B₂ in FIG. 1B) in a neural network. In at least one embodiment, all operations 605, 615, 625 are automatically performed by or under control of a controller, without user input or intervention. In at least one embodiment, one or more advantages described herein are achievable in the method 600.

The described methods and algorithms include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

FIG. 7 is a block diagram of a computer system 700 in accordance with some embodiments.

In some embodiments, system 700 is a general purpose computing device including a hardware processor 702 and a non-transitory, computer-readable storage medium 704. Storage medium 704, amongst other things, is encoded with, i.e., stores, computer program code 706, i.e., a set of executable instructions. Execution of instructions 706 by hardware processor 702 implements a portion or all of the methods or processes or operations described herein in accordance with one or more embodiments (hereinafter, the noted processes and/or methods).

Processor 702 is electrically coupled to computer-readable storage medium 704 via a bus 708. Processor 702 is also electrically coupled to an I/O interface 710 by bus 708. A network interface 712 is also electrically connected to processor 702 via bus 708. Network interface 712 is connected to a network 714, so that processor 702 and computer-readable storage medium 704 are capable of connecting to external elements via network 714. Processor 702 is configured to execute computer program code 706 encoded in computer-readable storage medium 704 in order to cause system 700 to be usable for performing a portion or all of the noted processes and/or methods. In one or more embodiments, processor 702 is a central processing unit (CPU), a multi-processor, a distributed processing system, an application specific integrated circuit (ASIC), and/or a suitable processing unit.

In one or more embodiments, computer-readable storage medium 704 is an electronic, magnetic, optical, electromagnetic, infrared, and/or a semiconductor system (or apparatus or device). For example, computer-readable storage medium 704 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 704 includes a compact disk-read only memory (CD-ROM), a compact disk-read/write (CD-R/W), and/or a digital video disc (DVD).

In one or more embodiments, storage medium 704 stores computer program code 706 configured to cause system 700 to be usable for performing a portion or all of the noted processes and/or methods. In one or more embodiments, storage medium 704 also stores information which facilitates performing a portion or all of the noted processes and/or methods.

System 700 includes I/O interface 710. I/O interface 710 is coupled to external circuitry. In one or more embodiments, I/O interface 710 includes a keyboard, keypad, mouse, trackball, trackpad, touchscreen, and/or cursor direction keys for communicating information and commands to processor 702.

System 700 also includes network interface 712 coupled to processor 702. Network interface 712 allows system 700 to communicate with network 714, to which one or more other computer systems are connected. Network interface 712 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 700.

System 700 is configured to receive information through I/O interface 710. The information received through I/O interface 710 includes one or more of instructions, data, design rules, libraries of standard cells, and/or other parameters for processing by processor 702. The information is transferred to processor 702 via bus 708. System 700 is configured to receive information related to a UI through I/O interface 710. The information is stored in computer-readable medium 704 as user interface (UI) 742.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application. In some embodiments, a portion or all of the noted processes and/or methods is implemented as a software application that is used by system 700.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

In some embodiments, an integrated circuit comprises a first array of resistors, a second array of resistors, and a plurality of interface circuits electrically coupled between the first array of resistors and the second array of resistors. Each interface circuit among the plurality of interface circuits is configured to receive a signal from the first array of resistors, and apply an analog voltage corresponding to the signal to the second array of resistors.

In some embodiments, an integrated circuit comprises a first array of resistors, a second array of resistors, and at least one interface circuit electrically coupled between the first array of resistors and the second array of resistors. The at least one interface circuit comprises a comparator circuit having a first input configured to receive an intermediate voltage corresponding to a current output from the first array of resistors, a driving circuit electrically coupled to an output of the comparator circuit, and a feedback circuit electrically coupling an output of the driving circuit to a second input of the comparator circuit. The driving circuit is configured to generate an analog voltage, and output the analog voltage to the second array of resistors. The feedback circuit is configured to apply a feedback voltage corresponding to the analog voltage to the second input of the comparator circuit. The comparator circuit is configured to perform a comparison between the intermediate voltage and the feedback voltage, and control the driving circuit to generate the analog voltage in accordance with a result of the comparison.

In some embodiments, an integrated circuit comprises a first array of resistors, a second array of resistors, and at least one interface circuit electrically coupled between the first array of resistors and the second array of resistors. The at least one interface circuit comprises an operational amplifier, a transistor and a feedback circuit. The operational amplifier has a first input electrically coupled to the first array of resistors, a second input, and an output. The transistor has a gate terminal electrically coupled to the output of the operational amplifier, a first source/drain terminal electrically coupled to the second array of resistors, and a second source/drain terminal electrically coupled to a node of a power supply voltage. The feedback circuit is electrically coupled between the first source/drain terminal of the transistor and the second input of the operational amplifier.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first array of resistors;
a second array of resistors; and
a plurality of interface circuits electrically coupled between the first array of resistors and the second array of resistors,
wherein each interface circuit among the plurality of interface circuits is configured to
receive a signal from the first array of resistors, and
apply an analog voltage corresponding to the signal to the second array of resistors.

2. The integrated circuit of claim 1, wherein
at least one resistor among the resistors in the first array or the second array is a controllably variable resistor.

3. The integrated circuit of claim 1, wherein
at least one resistor among the resistors in the first array or the second array is a memory cell.

4. The integrated circuit of claim 1, wherein
the first array of resistors and the second array of resistors configure a neural network.

5. The integrated circuit of claim 4, wherein
the second array of resistors comprises an output layer of the neural network, and
the integrated circuit further comprises a plurality of analog-to-digital converter (ADC) circuits electrically coupled to output conductive lines of the second array of resistors.

6. The integrated circuit of claim 4, further comprising:
a third array of resistors; and
a plurality of further interface circuits electrically coupled between the second array of resistors and the third array of resistors,
wherein each further interface circuit among the plurality of further interface circuits is configured to
receive a further signal from the second array of resistors, and
apply a further analog voltage corresponding to the further signal to the third array of resistors.

7. The integrated circuit of claim 1, wherein
said each interface circuit among the plurality of interface circuits comprises:
an integrator circuit configured to receive the signal, and integrate the signal over time to generate an intermediate voltage, and
a buffer circuit electrically coupled to the integrator circuit to receive the intermediate voltage, and configured to generate the analog voltage corresponding to the intermediate voltage.

8. The integrated circuit of claim 7, wherein
the buffer circuit comprises:
a comparator circuit having a first input electrically coupled to an output of the integrator circuit to receive the intermediate voltage,
a driving circuit electrically coupled to an output of the comparator circuit, and
a feedback circuit electrically coupling an output of the driving circuit to a second input of the comparator circuit,
the driving circuit is configured to generate the analog voltage under control of the comparator circuit,
the feedback circuit is configured to apply a feedback voltage corresponding to the analog voltage to the second input of the comparator circuit, and
the comparator circuit is configured to
perform a comparison between the intermediate voltage and the feedback voltage, and
control the driving circuit to generate the analog voltage in accordance with a result of the comparison.

9. The integrated circuit of claim 8, wherein
the buffer circuit further comprises a switch electrically coupled between the output of the driving circuit and an input conductive line of the second array of resistors.

10. An integrated circuit, comprising:
a first array of resistors;
a second array of resistors; and
at least one interface circuit electrically coupled between the first array of resistors and the second array of resistors,
wherein
the at least one interface circuit comprises:
a comparator circuit having a first input configured to receive an intermediate voltage corresponding to a current output from the first array of resistors;
a driving circuit electrically coupled to an output of the comparator circuit; and
a feedback circuit electrically coupling an output of the driving circuit to a second input of the comparator circuit,
the driving circuit is configured to generate an analog voltage, and output the analog voltage to the second array of resistors,
the feedback circuit is configured to apply a feedback voltage corresponding to the analog voltage to the second input of the comparator circuit, and
the comparator circuit is configured to
perform a comparison between the intermediate voltage and the feedback voltage, and
control the driving circuit to generate the analog voltage in accordance with a result of the comparison.

11. The integrated circuit of claim 10, the interface circuit further comprising:
a switch electrically coupled between the output of the driving circuit and an output of the interface circuit.

12. The integrated circuit of claim 10, further comprising:
an operational amplifier which has
a first input configured to receive the current output from the first array of resistors,
a second input which is grounded, and
an output configured to output the intermediate voltage, and
a capacitor which is electrically coupled between the first input and the output of the operational amplifier.

13. The integrated circuit of claim 10, wherein
the comparator circuit comprises an operational amplifier having a first input, a second input and an output correspondingly configuring the first input, the second input and the output of the comparator circuit, and
the driving circuit comprises a transistor having
a gate terminal electrically coupled to the output of the operational amplifier,
a first source/drain terminal configuring the output of the driving circuit, and
a second source/drain terminal electrically coupled to a node of a power supply voltage.

14. The integrated circuit of claim 10, wherein the feedback circuit comprises:
a connector having
a first end electrically coupled to the output of the driving circuit, and
a second end electrically coupled to the second input of the comparator circuit, and
a transistor having
a controllable gate terminal,
a first source/drain terminal electrically coupled to the output of the driving circuit and the first end of the connector, and
a second source/drain terminal which is grounded.

15. The integrated circuit of claim 10, wherein the feedback circuit comprises:
a resistor divider having a first resistor and a second resistor electrically coupled in series between the output of the driving circuit and the ground, and
a connector having
a first end electrically coupled to a node between the first resistor and the second resistor of the resistor divider, and
a second end electrically coupled to the second input of the comparator circuit.

16. The integrated circuit of claim 10, wherein the feedback circuit comprises:
a connector having
a first end electrically coupled to the output of the driving circuit, and
a second end electrically coupled to the second input of the comparator circuit, and
an offset voltage circuit electrically coupled to the connector, and configured to apply an offset voltage to the second input of the comparator circuit.

17. An integrated circuit, comprising:
a first array of resistors;
a second array of resistors; and
at least one interface circuit electrically coupled between the first array of resistors and the second array of resistors,
wherein the at least one interface circuit comprises:
an operational amplifier having
a first input electrically coupled to the first array of resistors,
a second input, and
an output;
a transistor having
a gate terminal electrically coupled to the output of the operational amplifier,
a first source/drain terminal electrically coupled to the second array of resistors, and
a second source/drain terminal electrically coupled to a node of a power supply voltage; and
a feedback circuit electrically coupled between the first source/drain terminal of the transistor and the second input of the operational amplifier.

18. The integrated circuit of claim 17, wherein the feedback circuit comprises:
a connector having
a first end electrically coupled to the first source/drain terminal of the transistor, and
a second end electrically coupled to the second input of the operational amplifier, and
a further transistor having
a controllable gate terminal,
a first source/drain terminal electrically coupled to the first end of the connector, and
a second source/drain terminal which is grounded.

19. The integrated circuit of claim 17, wherein the feedback circuit comprises:
a resistor divider having a first resistor and a second resistor electrically coupled in series between the first source/drain terminal of the transistor and the ground, and
a connector having
a first end electrically coupled to a node between the first resistor and the second resistor of the resistor divider, and
a second end electrically coupled to the second input of the operational amplifier.

20. The integrated circuit of claim 17, wherein the feedback circuit comprises:
a connector having
a first end electrically coupled to the first source/drain terminal of the transistor, and
a second end electrically coupled to the second input of the operational amplifier, and
an offset voltage circuit electrically coupled to the connector, and configured to apply an offset voltage to the second input of the operational amplifier.
